(19) United States
(12) Patent Application Publication
(10) Pub. No.: US 2016/0349469 A1
(43) Pub. Date: Dec. 1, 2016

(54) MANUFACTURING METHOD OF PRINTED CIRCUIT BOARD, PRINTED CIRCUIT BOARD, AND OPTICAL DEVICE

(71) Applicant: FUJITSU LIMITED, Kawasaki-shi (JP)

(72) Inventor: Mariko KASE, lsehara (JP)

(73) Assignee: FUJITSU LIMITED, Kawasaki-shi (JP)

(21) Appl. No.: 15/131,398

(22) Filed: Apr. 18, 2016

(30) Foreign Application Priority Data
Jun. 1, 2015 (JP) 2015-111088

(51) Int. Cl. G02B 6/42; B29C 39/02; H01S 5/183; B29C 35/08; G02B 6/32; G02B 6/138

(52) U.S. Cl. CPC G02B 6/4244; G02B 6/4206; G02B 6/4214; G02B 6/32; G02B 6/138; G02B 6/428; H01S 5/183; B29C 35/0805; B29C 39/02; B29C 39/021; B29C 2035/0827; B29L 2011/0016

(57) ABSTRACT

A method of manufacturing a printed circuit board, the method includes: forming an electrode layer on one surface of a substrate; forming a through hole that penetrates the substrate and the electrode layer, wherein an inner diameter of the through hole in the electrode layer is smaller than an inner diameter of the through hole in the substrate; dropping a curable liquid that has a liquid-repellency with respect to the substrate, on a substrate portion in the through hole from an opposite side to the electrode layer; and curing the liquid dropped on the substrate portion in the through hole to form a lens.

### CROSS-REFERENCE TO RELATED APPLICATIONS

This application is based upon and claims the benefit of priority of the prior Japanese Patent Application No. 2015-111088 filed on Jun. 1, 2015, the entire contents of which are incorporated herein by reference.

### FIELD

The embodiments discussed herein are related to a method of manufacturing a printed circuit board, the printed circuit board, and an optical device.

### BACKGROUND

The application of light to a relatively short distance communication such as a communication between the servers and between boards has conventionally been in progress. Further, a technology of forming a lens in a through hole provided in a printed circuit board used in an optical receiving device or an optical transmission device is known.

However, in the above-described conventional technology, there is a problem in that in an optical receiving device or an optical transmission device using a printed circuit board, it is difficult to position and form a lens with a small curvature radius with high precision. When the curvature radius of a lens is large, or the positioning accuracy of a lens is low, for example, the coupling efficiency of light may be decreased so that a light transmission characteristic in an optical receiving device or an optical transmission device may be degraded.

The followings are reference documents.

[Document 1] International Publication Pamphlet No. WO2007/105419,

### [Document 2] Japanese Laid-open Patent Publication No. 2013-205603, and

[Document 3] International Publication Pamphlet No. WO2012/043417.

### SUMMARY

According to an aspect of the invention, a method of manufacturing a printed circuit board, the method includes: forming an electrode layer on one surface of a substrate; forming a through hole that penetrates the substrate and the electrode layer, wherein an inner diameter of the through hole in the electrode layer is smaller than an inner diameter of the through hole in the substrate; dropping a curable liquid that has a liquid-repellency with respect to the substrate, on a substrate portion in the through hole from an opposite side to the electrode layer; and curing the liquid dropped on the substrate portion in the through hole to form a lens.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a front sectional view illustrating an exemplary optical device according to a first exemplary embodiment;

FIG. 2 is a view illustrating an exemplary characteristic of a lens according to the first exemplary embodiment;

FIG. 3 is a view illustrating an exemplary printed circuit board according to the first exemplary embodiment;

FIG. 4 is a front sectional view illustrating an exemplary manufacturing process of the optical device according to the first exemplary embodiment (part 1);

FIG. 5 is a front sectional view illustrating an exemplary manufacturing process of the optical device according to the first exemplary embodiment (part 2);

FIG. 6 is a plan view illustrating an exemplary top surface of the optical device according to the first exemplary embodiment;

FIG. 7 is a front sectional view illustrating another exemplary optical device according to the first exemplary embodiment;

FIG. 8 is a front sectional view illustrating an exemplary optical device according to a second exemplary embodiment;

FIG. 9 is a front sectional view illustrating an exemplary manufacturing process of the optical device according to the second exemplary embodiment (part 1);

FIG. 10 is a front sectional view illustrating an exemplary manufacturing process of the optical device according to the second exemplary embodiment (part 2);

FIG. 11 is front sectional view illustrating an exemplary manufacturing process of the optical device according to the second exemplary embodiment (part 3);

FIG. 12 is a front sectional view illustrating another exemplary optical device according to the second exemplary embodiment;

FIG. 13 is a front sectional view illustrating a further exemplary optical device according to the second exemplary embodiment;

FIG. 14 is a view illustrating an exemplary simulation result of a coupling loss amount in an optical device according to each exemplary embodiment (part 1);

FIG. 15 is a view illustrating an exemplary simulation result of a coupling loss amount in an optical device according to each exemplary embodiment (part 2); and

FIG. 16 is a view illustrating an exemplary simulation result of a coupling loss amount in an optical device according to each exemplary embodiment (part 3).

### DESCRIPTION OF EMBODIMENTS

Hereinafter, detailed descriptions will be made on exemplary embodiments of a manufacturing method, a printed circuit board, and an optical device according to the present disclosure with reference to drawings.

### First Exemplary Embodiment

### Optical Device According to First Embodiment

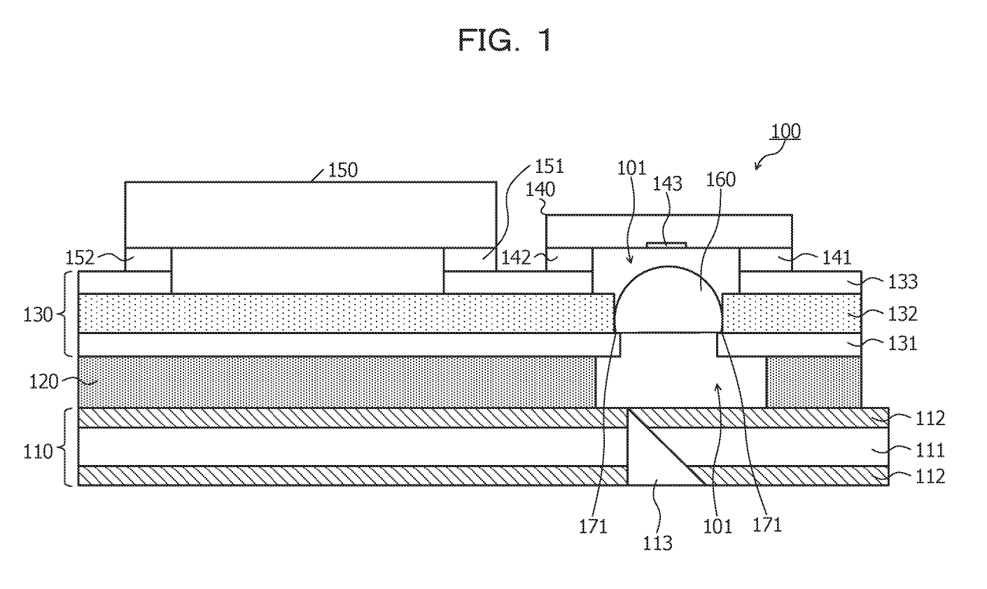

FIG. 1 is a front sectional view illustrating an exemplary optical device according to a first exemplary embodiment. As illustrated in FIG. 1, the optical device 100 according to the first exemplary embodiment is an optical receiving device that includes an optical waveguide 110, an adhesive layer 120, a printed circuit board 130, a light receiving element 140, a trans-impedance amplifier (TIA) 150, and a lens 160.

The optical waveguide 110 includes a core 111 and a clad 112. The core 111 is surrounded by the clad 112. The core 111 has a higher refractive index than the clad 112. Light incident into the optical waveguide 110 propagates while being reflected at the boundary surface between the core 111 and the clad 112 within the core 111. The diameter of the core 111 may be set to, for example, about 50 [μm].

In addition, a 45 degree mirror 113 is formed in the optical waveguide 110. The 45 degree mirror 113 is formed such that a reflecting surface slants at 45° with respect to the propagation direction of light in the core 111. Then, the 45 degree mirror 113 reflects and emits the light propagating through the core 111 toward the light receiving element 140. The 45 degree mirror 113 may be formed by partially scraping and polishing, for example, the core 111 and the clad 112.

The adhesive layer 120 is a layer for bonding the optical waveguide 110 to the printed circuit board 130. As the adhesive layer 120, for example, a double-sided adhesive sheet may be employed.

The printed circuit board 130 is a flexible printed circuit (FPC) board that includes a rear electrode 131, a substrate 132, and a front electrode 133. As the substrate 132, for example, a flexible material such as polyimide may be used. The rear electrode 131 is an electrode layer of a ground electrode formed, for example, on one surface (a rear surface) of the substrate 132. Meanwhile, the rear electrode 131 may include, for example, a signal electrode without being limited to the ground electrode. The front electrode 133 is a signal electrode formed on the other surface (a top surface) of the substrate 132.

A through hole 101 is formed in a portion of the adhesive layer 120 and the printed circuit board 130 between the 45 degree mirror 113 and the light receiving element 140 so as to pass light therethrough. The through hole 101 is formed to be narrower than the distance between electrodes 141 and 142 of the light receiving element 140 so that the light receiving element 140 may be provided to face the printed circuit board 130.

The through hole 101 is formed by providing, for example, a cylindrical hole in each of the rear electrode 131, the substrate 132 and the front electrode 133. Meanwhile, the hole formed in each of the substrate 132 and the front electrode 133 may take various shapes such as, for example, a polygonal shape without being limited to a cylindrical shape.

A lens 160 is formed in the through hole 101 to condense the light emitted from the 45 degree mirror 113 on a light receiving portion 143 of the light receiving element 140. The lens 160 is a micro lens directly formed on the printed circuit board 130 by an inkjet method. As a material of the lens 160, for example, a UV curable resin may be used which has a reflow resistance and is cured by irradiation of UV (rays). The distance between the lens 160 and the light receiving element 140 may be adjusted by, for example, the thickness of the substrate 132 and the front electrode 133.

For example, the through hole 101 is formed such that the inner diameter in the rear electrode 131 portion is smaller than the inner diameter in the substrate 132 and front electrode 133 portions. Accordingly, when the through hole 101 is viewed from the light receiving element 140 side, the rear electrode 131 is exposed in a ring shape in the inside of the hole of the substrate 132. The lens 160 is formed to be in contact with the inner periphery of the hole of the substrate 132 while the exposed portion of the rear electrode 131 serves as a support base 171.

As an example, the inner diameter of the substrate 132 portion in the through hole 101 may be set to about 100 [μm] and the inner diameter of the rear electrode 131 portion in the through hole 101 may be set to be about 80 [μm] or 90 [μm].

The light receiving element 140 and the TIA 150 are provided to face the top surface of the printed circuit board 130 by, for example, flip chip mounting. The light receiving element 140 includes the electrodes 141 and 142, and the light receiving portion 143. The light receiving element 140 is provided on the top surface of the printed circuit board 130 such that the light receiving portion 143 is directed to the 45 degree mirror 113. The light receiving element 140 is connected to the front electrode 133 by the electrodes 141 and 142.

The light receiving element 140 receives, by the light receiving portion 143, the light emitted from the 45 degree mirror 113. Then, the light receiving element 140 outputs, through the front electrode 133, an electrical signal according to the intensity of the received light to the TIA 150. The light receiving element 140 may be realized by, for example, a photo diode (PD) capable of receiving light with a wavelength of 850 [nm]. In a case where the light receiving element 140 receives a high-speed optical signal, the diameter of the light receiving portion 143 is minimized. For example, the diameter of the light receiving portion 143 may be set to about 25 [μm].

The TIA 150 includes electrodes 151 and 152, and is connected to the front electrode 133 by the electrodes 151 and 152. The TIA 150 converts the electrical signal output from the light receiving element 140 through the front electrode 133 from a current value signal to a voltage value signal. Then, the TIA 150 outputs the electrical signal converted into the voltage value signal to a circuit for processing the electrical signal.

For example, since a distance corresponding to the thickness of the adhesive layer 120 and the printed circuit board 130 is present between the optical waveguide 110 and the light receiving element 140, the light emitted from the 45 degree mirror 113 to the through hole 101 is diffused. In contrast, when the lens 160 is provided in the through hole 101, the light may be condensed, and the coupling efficiency in the light receiving element 140 may be improved.

(Characteristic of Lens According to First Exemplary Embodiment)

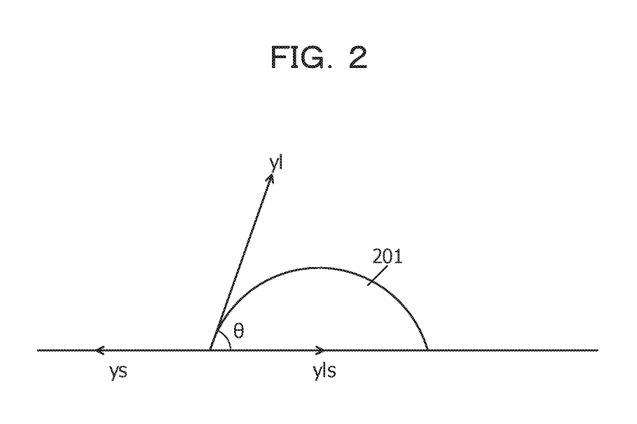

FIG. 2 is a view illustrating an exemplary characteristic of a lens according to the first exemplary embodiment. A droplet 201 illustrated in FIG. 2 is a non-cured droplet (liquid) for forming the lens 160. As the droplet 201, for example, an acrylate-based UV curable resin with a viscosity of less than 30[mPa·s] may be used. In FIG. 2, symbol “ys” represents a surface tension of the substrate 132. Symbol “yls” represents an interfacial tension of the droplet 201 and the substrate 132. Symbol “yl” represents a surface tension of the droplet 201. Symbol “θ” represents a contact angle of the droplet 201 with respect to the substrate 132. In the equilibrium state of the droplet 201, the following Equations (1) and (2) are satisfied.

ys=yl·cos θ+ysl (1)

cos θ=(ys−ysl)/yl (2)

The general surface tension (ys) of polyimide used in the substrate 132 is, for example, about 20 [mN/m]. The general surface tension (yl) of the UV curable resin used in the droplet 201 is, for example, about 40 [mN/m]. Accordingly, from Equations (1) and (2) above, cos θ becomes ½ or less (the contact angle is 60° or more) and thus it can be said that the droplet 201 and the polyimide used in the substrate 132 have a liquid-repellent relationship.

When the lens 160 is formed using an inkjet method, the curvature radius of the lens 160 is determined by the contact angle of the droplet 201 with respect to the substrate 132. As described above, since the droplet 201 and the polyimide used in the substrate 132 have a liquid-repellent relationship, the curvature radius of the lens 160 may be decreased by increasing the contact angle of the droplet 201 with respect to the substrate 132. Therefore, the light emitted from the 45 degree mirror 113 may be condensed at a short focal length on the light receiving portion 143 with an extremely small diameter.

(Printed Circuit Board According to First Exemplary Embodiment)

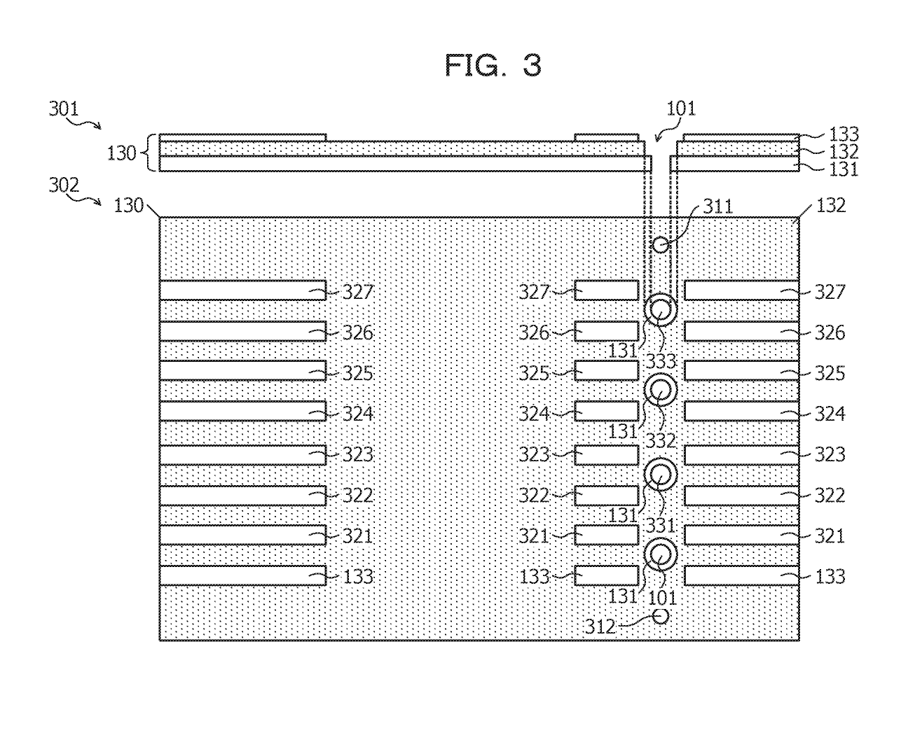

FIG. 3 is a view illustrating an exemplary printed circuit board according to the first exemplary embodiment. In FIG. 3, the same parts as those illustrated in FIG. 1 are denoted by the same reference numerals, and descriptions thereof will be omitted. FIG. 3 illustrates a front sectional view 301 and a plan view 302 which correspond to the front sectional view and the plan view of the printed circuit board 130 illustrated in FIG. 1, respectively. The front sectional view 301 and the plan view 302 illustrate the printed circuit board 130 before the lens 160 is formed in the through hole 101.

In the example illustrated in FIG. 3, descriptions will be made on a case where the light receiving element 140 is a PD array that includes a plurality of light receiving portions (e.g., four (4) light receiving portions). As illustrated in the plan view 302, for example, front electrodes 321 to 327 are arranged on the top surface of the substrate 132 of the printed circuit board 130, in addition to the front electrode 133. Through holes 331 to 333 are formed on the top surface of the substrate 132, in addition to the through hole 101. As in the through hole 101, in each of the through holes 331 to 333, the rear electrode 131 is exposed in a ring shape at the inside of the hole of the substrate 132, and each lens is formed using an exposed portion of the rear electrode 131 as a support base.

For example, the front electrodes 133 and 321 and the through hole 101 correspond to a first light receiving portion of the light receiving element 140 (e.g., the light receiving portion 143). The front electrodes 322 and 323 and the through hole 331 correspond to a second light receiving portion of the light receiving element 140. The front electrodes 324 and 325 and the through hole 332 correspond to a third light receiving portion of the light receiving element 140. The front electrodes 326 and 327, and the through hole 333 correspond to a fourth light receiving portion of the light receiving element 140. Although not illustrated in FIG. 3, first to fourth cores are formed in the optical waveguide 110 to correspond to the first to fourth light receiving portions of the light receiving element 140, respectively.

Markers 311 and 312 for alignment are formed on the substrate 132. The markers 311 and 312 are markers such as, for example, through holes, processing marks, or printing that may be used for alignment through image processing. For example, the markers 311 and 312 are used for positioning when the through holes 101 and 331 to 333 are formed in the printed circuit board 130, or when the light receiving element 140 or the TIA 150 is mounted on the printed circuit board 130.

The through holes 101 and 331 to 333 may be formed by shaving the substrate 132 and the rear electrode 131 through, for example, etching from the front electrode 133 and 321 to 327 side using, for example, a mask corresponding to the markers 311 and 312. Accordingly, the through holes 101 and 331 to 333 may be formed with high precision.

(Manufacturing Process of Optical Device According to First Exemplary Embodiment)

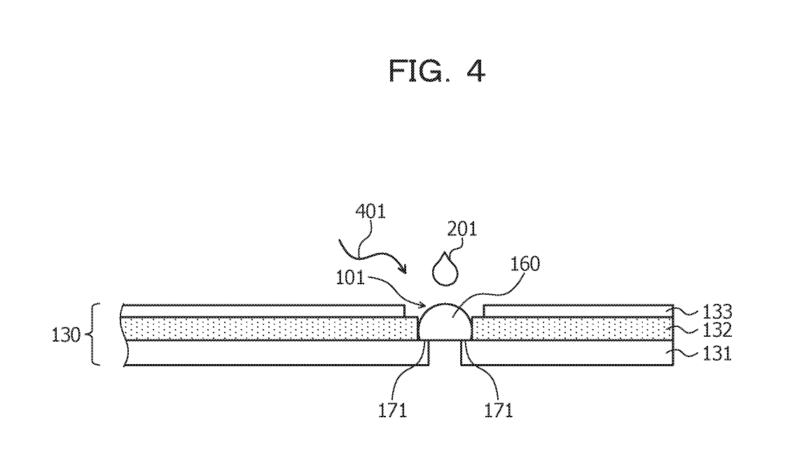

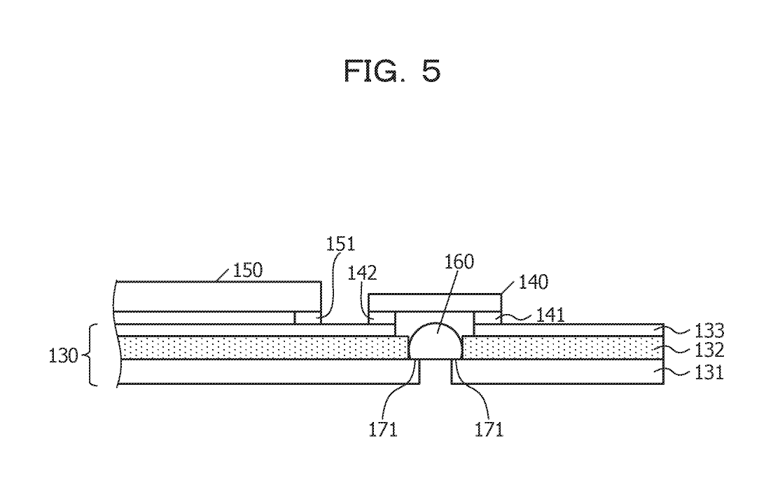

FIGS. 4 and 5 are front sectional views each illustrating an exemplary manufacturing process of the optical device according to the first exemplary embodiment. In FIGS. 4 and 5, the same parts as those illustrated in FIG. 1 are denoted by the same reference numerals, and descriptions thereof will be omitted. The optical device 100 according to the first exemplary embodiment may be manufactured using, for example, the processes illustrated in FIGS. 4 and 5. Each of the processes illustrated in FIGS. 4 and 5 is performed by a manufacturing device such as, for example, a robot that assembles respective parts such as, for example, the optical waveguide 110, the printed circuit board 130, the light receiving element 140, and the TIA 150 while recognizing each of the parts by image processing.

First, as illustrated in FIG. 4, the printed circuit board 130 is provided such that the rear electrode 131 is placed downwards, and the front electrode 133 is placed upwards. Then, the lens 160 is formed by an inkjet method so that the lens 160 is integrated on the printed circuit board 130. As the inkjet method, various types of inkjet methods such as, for example, a piezo-type method and a thermal-type method may be used. For example, the droplet 201 is dropped to be placed on the support base 171 of the through hole 101 formed in the printed circuit board 130. Then, the droplet 201 placed on the support base 171 is subjected to a UV irradiation 401 to be cured to form the lens 160.

Then, as illustrated in FIG. 5, the light receiving element 140 and the TIA 150 are mounted on the top surface of the printed circuit board 130 to be electrically connected to the front electrode 133. Here, the positions of the light receiving element 140 and the TIA 150 with respect to the printed circuit board 130 may be adjusted by, for example, image processing based on the markers 311 and 312 illustrated in FIG. 3. Then, the optical waveguide 110 is formed on the printed circuit board 130 at the rear electrode 131 side through the adhesive layer 120. Thus, for example, the optical device 100 illustrated in FIG. 1 may be manufactured.

An optical characteristic such as, for example, a focal length of the lens 160 may be adjusted according to, for example, the amount of the droplet 201. The amount of the droplet 201 required for a desired optical characteristic of the lens 160 may be specified by, for example, an experiment or a simulation and set in an inkjet device for dropping the droplet 201. Since the amount of the droplet 201 may be controlled with high precision using the inkjet method, the optical characteristic of the droplet 201 may be adjusted with high precision. The droplet 201 may be divisionally dropped a plurality of times to adjust the amount of the droplet 201.

For example, the droplet 201, which has been dropped to be placed on a dam structure constituted by the support base 171 of the through hole 101 and the substrate 132, is automatically moved to the most stable center of the dam (i.e., the hole center of the through hole 101) due to a leveling phenomenon. This may substantially eliminate a tolerance in positional accuracy between the center of the lens 160 formed by curing the droplet 201 and the hole center of the through hole 101.

An optical element such as, for example, the light receiving element 140 may be mounted based on the markers 311 and 312 of the printed circuit board 130. Then, since the through hole 101 of the printed circuit board 130 may be formed together with the markers 311 and 312 with high precision through, for example, etching, the positional displacement between the light receiving element 140 and the lens 160 may be suppressed.

Thus, the manufacturing of the optical device 100 is facilitated. Since the lens 160 is integrated on the printed circuit board 130, the printed circuit board 130 and the lens 160 may be handled as a single member. Thus, the number of members before assembled may be decreased. Accordingly, a reduction of, for example, a component cost, a management cost, and an assembly cost may be achieved.

(Top Surface of Optical Device According to First Exemplary Embodiment)

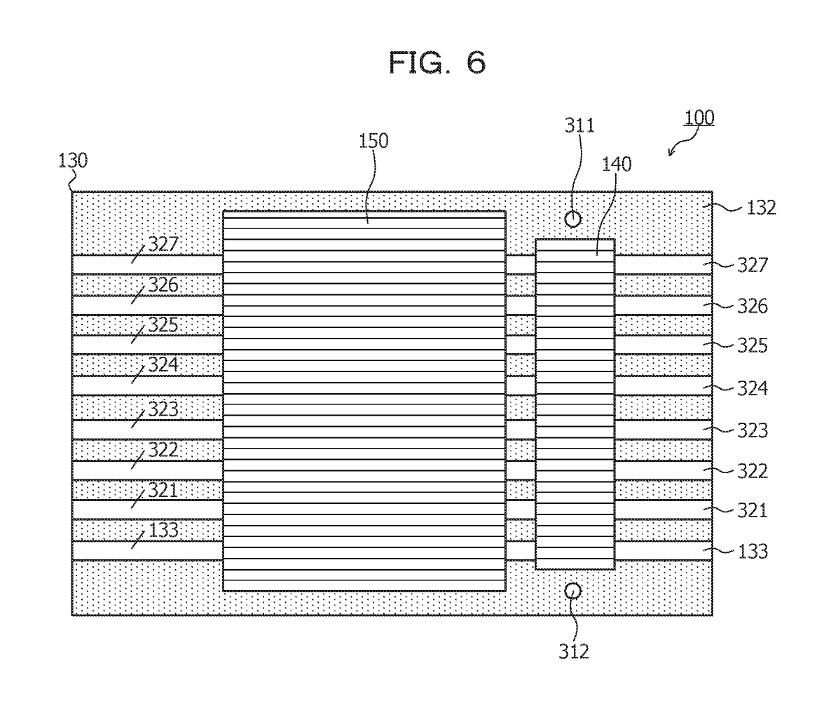

FIG. 6 is a plan view illustrating an exemplary top surface of the optical device according to the first exemplary embodiment. In FIG. 6, the same parts as those illustrated in FIG. 3 are denoted by the same reference numerals, and descriptions thereof will be omitted. When the light receiving element 140 and the TIA 150 are mounted on the top surface of the printed circuit board 130, the light receiving element 140 and the TIA 150 may be connected to each other by the front electrodes 133 and 321 to 327 as illustrated in FIG. 6.

(Another Exemplary Optical Device According to First Exemplary Embodiment)

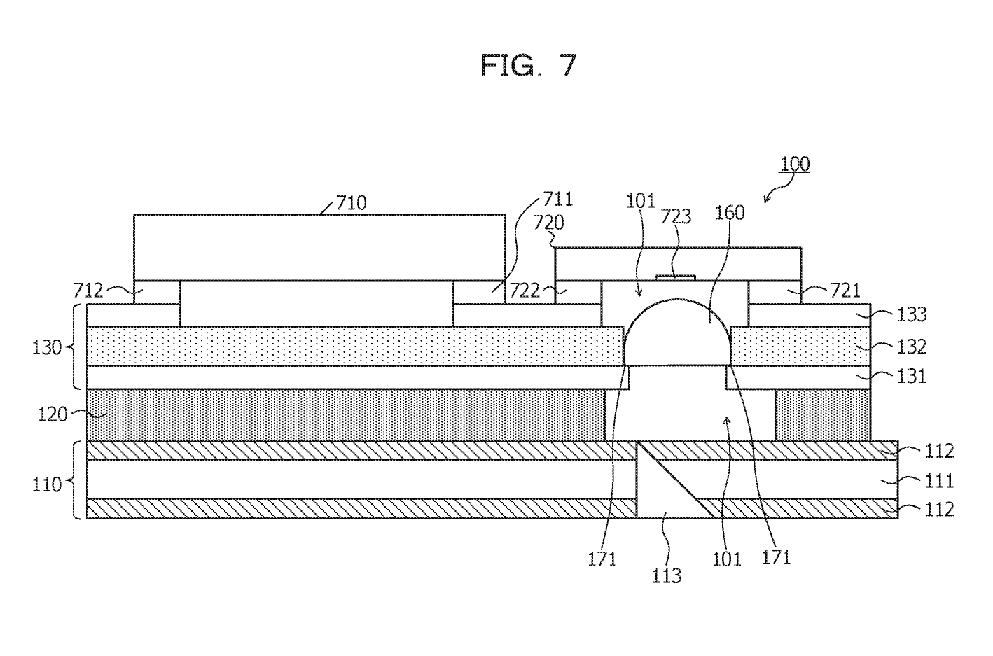

FIG. 7 is a front sectional view illustrating another exemplary optical device according to the first exemplary embodiment. In FIG. 7, the same parts as those illustrated in FIG. 1 are denoted by the same reference numerals, and descriptions thereof will be omitted. As illustrated in FIG. 7, the optical device 100 according to the first exemplary embodiment may be an optical transmission device that includes the optical waveguide 110, the adhesive layer 120, the printed circuit board 130, and a driver 710, a light emitting element 720, and the lens 160.

The driver 710 is a driver integrated circuit (IC) configured to drive the light emitting element 720. The driver 710 is connected to the front electrode 133 by electrodes 711 and 712. For example, the driver 710 converts an input electrical signal from a voltage value signal to a current value signal, and outputs the electrical signal converted into the current value signal to the light emitting element 720 through the front electrode 133.

The light emitting element 720 includes electrodes 721 and 722 and a light emitting portion 723. The light emitting element 720 is provided on the top surface of the printed circuit board 130 such that the light emitting portion 723 is directed to the 45 degree mirror 113. The light emitting element 720 is connected to the front electrode 133 by the electrodes 721 and 722.

The light emitting element 720 emits light, which is output from the driver 710 through the front electrode 133 and has an intensity according to the electrical signal, toward the 45 degree mirror 113 by the light emitting portion 723. The light emitting element 720 may be realized by, for example, a laser diode (LD) capable of oscillating light with a wavelength of 850 [nm] such as, for example, a vertical cavity surface emitting laser (VCSEL).

The lens 160 condenses the light emitted from the light emitting element 720 on the portion of the core 111 of the optical waveguide 110 where the 45 degree mirror 113 is formed. The 45 degree mirror 113 reflects the light condensed by the lens 160 in the propagation direction of the light in the core 111 so that the light is incident on the core 111. Accordingly, the light emitted from the light emitting element 720 is propagated by the core 111.

For example, since a distance corresponding to the thickness of the adhesive layer 120 and the printed circuit board 130 is present between the optical waveguide 110 and the light emitting element 720, the light emitted from the light emitting element 720 to the through hole 101 is diffused. In contrast, when the lens 160 is provided in the through hole 101, the light may be condensed, and the coupling efficiency in the core 111 (the 45 degree mirror 113) may be improved.

As described above, by the manufacturing method according to the first exemplary embodiment, the through hole 101 is formed on the printed circuit board 130 such that the through hole 101 is narrower in the rear electrode 131 portion than in the substrate 132 portion. Then, the droplet 201 having a liquid-repellency with respect to the substrate 132 is dropped on the substrate 132 portion in the through hole 101. Accordingly, the droplet 201 having a large contact angle (i.e., a small curvature radius) is formed, and by curing the droplet 201, a lens 160 having a small curvature radius may be formed.

Since the dropped droplet 201 is automatically moved to the center of the through hole 101 due to a leveling phenomenon, the lens 160 may be positioned and formed with high precision by curing the droplet 201. The droplet 201 may be avoided from passing through the through hole 101 due to the support base 171 that is formed such that the through hole 101 is narrower in the rear electrode 131 portion than in the substrate 132 portion.

### Second Exemplary Embodiment

Some parts of the second exemplary embodiment which are different from those of the first exemplary embodiment will be described.

(Optical Device According to Second Exemplary Embodiment)

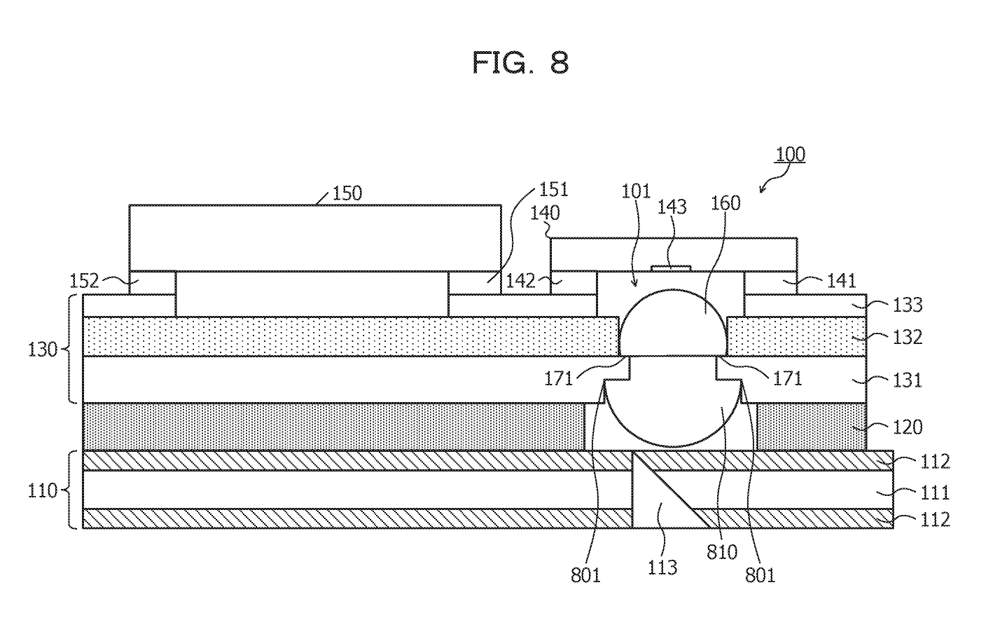

FIG. 8 is a front sectional view illustrating an exemplary optical device according to a second exemplary embodiment. In FIG. 8, the same parts as those illustrated in FIG. 1 are denoted by the same reference numerals, and descriptions thereof will be omitted. As illustrated in FIG. 8, the optical device 100 according to the second exemplary embodiment includes a lens 810 (a second lens), in addition to the lens 160 (a first lens). The lens 810 is formed using the rear electrode 131 of the printed circuit board 130 as a dam structure. The lens 810 is formed coaxially with, for example, the lens 160.

For example, a stepped portion 801, which surrounds the rear electrode 131 portion in the through hole 101 and has a step, is formed on the surface of the rear electrode 131 at the opposite side to the substrate 132. Accordingly, double edges (an inner edge and an outer edge) are formed on the rear electrode 131. The lens 810 is formed to be supported by the inner edge of the double edges formed by the stepped portion 801 of the rear electrode 131. The diameter and the height of the lens 810 are designed so that, for example, light emitted from the 45 degree mirror 113 may be efficiently condensed.

When the lenses 160 and 810 are used, the light may be condensed on the light receiving element 140 at a shorter distance as compared to a case where, for example, only the lens 160 is used. Therefore, the coupling efficiency of the light in, for example, the light receiving element 140 may be improved. Alternatively, a device may be miniaturized by suppressing the height of the lens 160.

(Manufacturing Process of Optical Device According to Second Exemplary Embodiment)

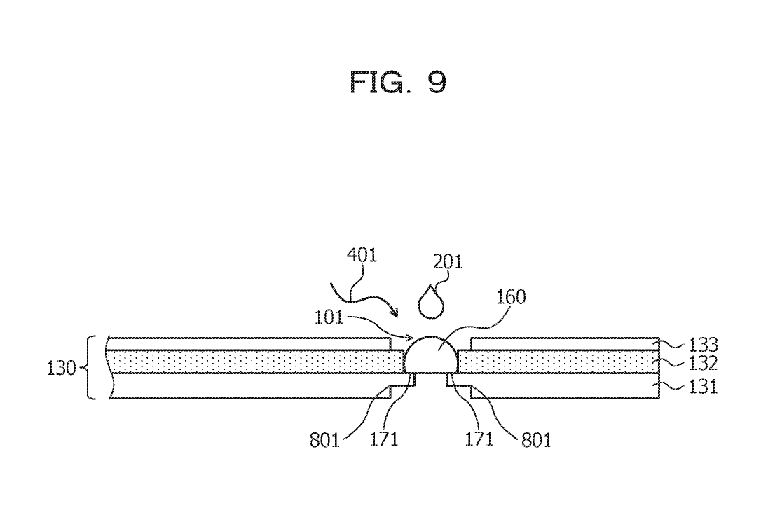

FIGS. 9 to 11 are front sectional views each illustrating an exemplary manufacturing process of the optical device according to the second exemplary embodiment. In FIGS. 9 to 11, the same parts as those illustrated in FIG. 1 are denoted by the same reference numerals, and descriptions thereof will be omitted. The optical device 100 according to the second exemplary embodiment may be manufactured using the processes illustrated in, for example, FIGS. 9 to 11. Each of the processes illustrated in FIGS. 9 to 11 is performed by a manufacturing device such as, for example, a robot that assembles respective parts such as, for example, the optical waveguide 110, the printed circuit board 130, the light receiving element 140, and the TIA 150 while recognizing each of the parts by image processing.

First, as illustrated in FIG. 9, the printed circuit board 130 is provided such that the rear electrode 131 is placed downwards, and the front electrode 133 is placed upwards. Here, in the printed circuit board 130, the stepped portion 801 is formed on the opposite surface of the rear electrode 131 with respect to the substrate 132. The stepped portion 801 may be formed by, for example, etching.

Then, the lens 160 is formed by an inkjet method so that the lens 160 is integrated on the printed circuit board 130. For example, the droplet 201 is dropped to be placed on the support base 171 of the through hole 101 formed in the printed circuit board 130. Then, the droplet 201 placed on the support base 171 is subjected to the UV irradiation 401 to be cured to form the lens 160.

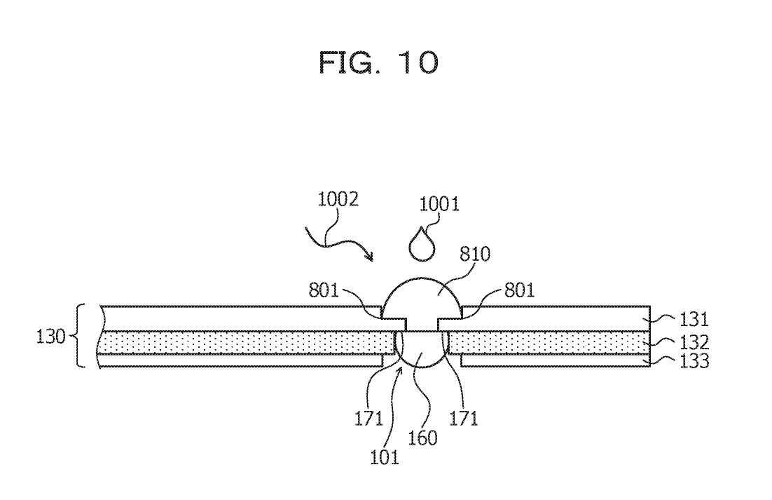

Here, as illustrated in FIG. 10, the printed circuit board 130 is provided such that the rear electrode 131 is placed upwards, and the front electrode 133 is placed downwards. Then, the lens 810 is formed by an inkjet method so that the lens 810 is integrated on the printed circuit board 130. For example, a droplet 1001 is dropped to be placed on the stepped portion 801 of the through hole 101 formed in the printed circuit board 130. Then, the droplet 1001 placed on the stepped portion 801 is subjected to a UV irradiation 1002 to be cured to form the lens 810. In the example illustrated in FIG. 10, the amount of the droplet 1001 is adjusted such that the lens 810 is supported by the inner edge formed by the stepped portion 801.

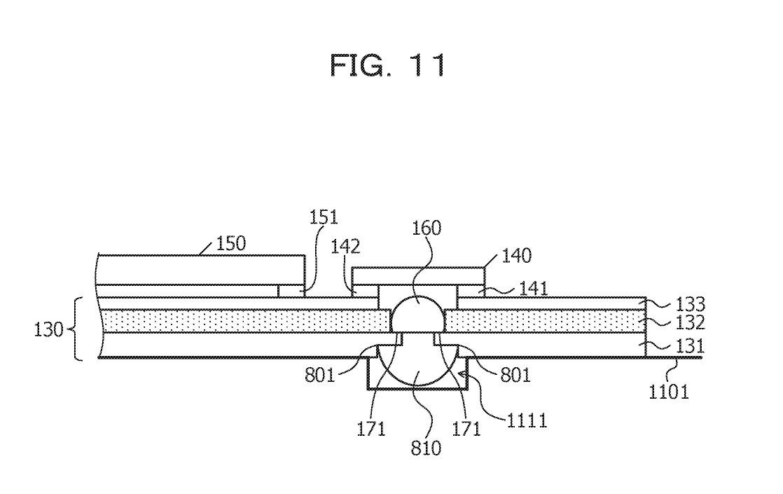

Then, as illustrated in FIG. 11, the printed circuit board 130 is provided such that the rear electrode 131 is placed downwards, and the front electrode 133 is placed upwards. Then, the light receiving element 140 and the TIA 150 are mounted on the top surface of the printed circuit board 130 to be electrically connected to the front electrode 133.

Here, when the lens 810 protrudes downwards from the rear electrode 131, a jig 1101 having a recess 1111 may be used. The printed circuit board 130 may be provided on the jig 1101 so that the lens 810 may be put in the recess 1111, and then the light receiving element 140 and the TIA 150 may be mounted. Accordingly, the light receiving element 140 and the TIA 150 may be mounted without imposing load on the lens 810.

(Another Exemplary Optical Device According to Second Exemplary Embodiment)

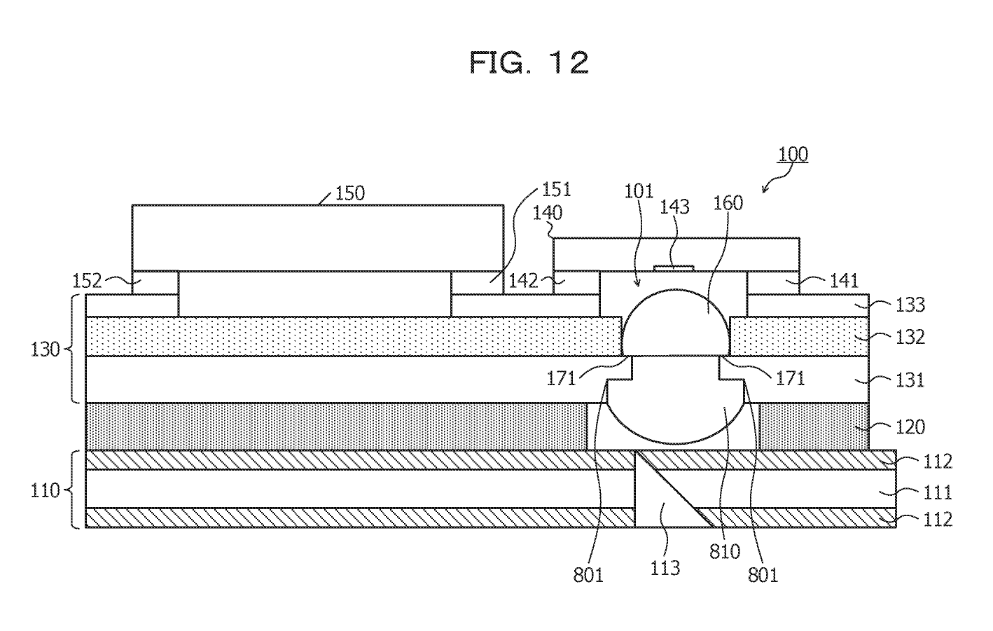

FIG. 12 is a front sectional view illustrating another exemplary optical device according to the second exemplary embodiment. In FIG. 12, the same parts as those illustrated in FIG. 8 are denoted by the same reference numerals, and descriptions thereof will be omitted. As illustrated in FIG. 12, the lens 810 may be formed to be supported by the outer edge formed by the stepped portion 801 of the rear electrode 131 by setting, for example, the amount of the droplet 1001 for forming the lens 810 to be larger than that of the example illustrated in FIG. 8.

Accordingly, the diameter and the height of the lens 810 may be increased as compared to a case where, for example, the lens 810 is supported by the inner edge of the rear electrode 131 (see, e.g., FIG. 8).

(Further Exemplary Optical Device According to Second Exemplary Embodiment)

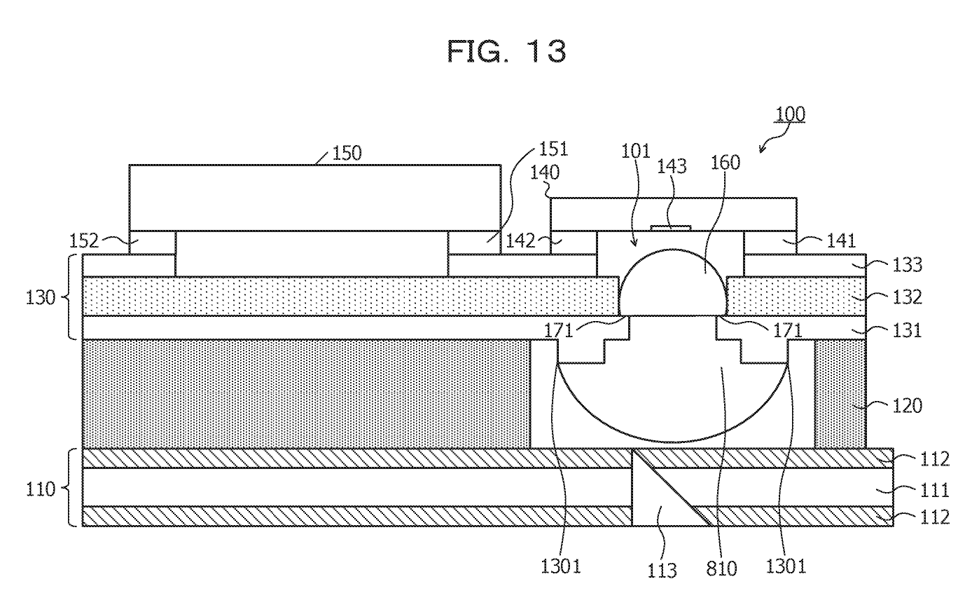

FIG. 13 is a front sectional view illustrating a further exemplary optical device according to the second exemplary embodiment. In FIG. 13, the same parts as those illustrated in FIG. 8 are denoted by the same reference numerals, and descriptions thereof will be omitted. As illustrated in FIG. 13, a convex portion 1301 may be formed around the through hole 101 in the rear electrode 131 at the opposite side to the substrate 132. The convex portion 1301 is formed in a ring shape to surround the through hole 101 when viewed from, for example, the 45 degree mirror 113 side.

In addition, the lens 810 may be formed to be supported by the outer edge of the double edges formed by the convex portion 1301 of the rear electrode 131. Accordingly, the diameter and the height of the lens 810 may be increased as compared to a case where, for example, the lens 810 is supported by the edge formed by the stepped portion 801 of the rear electrode 131 (see, e.g., FIGS. 8 and 12).

As illustrated in FIGS. 8, 12, and 13, a plurality of edges may be formed on the through hole 101 portion in the rear electrode 131 by forming the stepped portion 801 or the convex portion 1301 on the rear electrode 131. Then, by adjusting the amount of the droplet 1001, among the plurality of edges, an edge to be used for supporting the lens 810 may be changed so that the optical characteristic of the lens 810 may be adjusted.

Accordingly, although, for example, the shape of the printed circuit board 130 is not changed when a design is changed, the optical characteristic of the lens 810 may be adjusted by adjusting the amount of the droplet 1001, which enables a design to be flexibly changed.

As described above, by the manufacturing method according to the second exemplary embodiment, the stepped portion 801, which surrounds the rear electrode 131 portion in the through hole 101 and has a step, is formed on the surface of the rear electrode 131 at the opposite side to the substrate 132. In addition, on the rear electrode 131 portion in the through hole 101, the droplet 1001 is dropped from the opposite side to the substrate 132 and supported by the stepped portion 801, so that the lens 810 may be positioned and formed with high precision by curing the droplet 1001.

Since the lens 810 is formed in addition to the lens 160, light may be condensed on the light receiving element 140 at a shorter distance. Thus, the coupling efficiency of the light in, for example, the light receiving element 140 may be improved. Alternatively, a device may be miniaturized by suppressing the height of the lens 160.

In the optical device 100 according to the second exemplary embodiment, for example, as illustrated in FIG. 7, the driver 710 and the light emitting element 720 may be provided instead of the light receiving element 140 and the TIA 150, and the optical device 100 may be used as an optical transmission device.

Hereinafter, descriptions will be made on a coupling loss amount in the optical device 100 according to each of the above-described respective exemplary embodiments.

(Simulation Result of Coupling Loss Amount in Optical Device According to Each Embodiment)

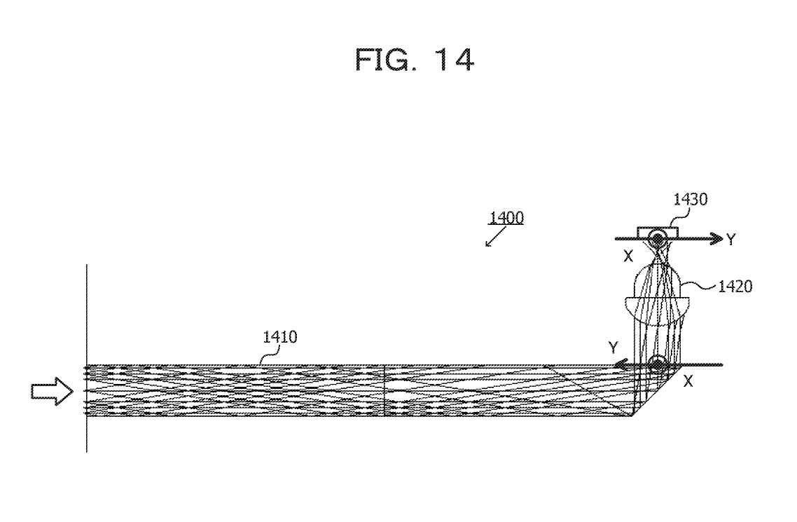

FIGS. 14 to 16 are views each of which illustrates an exemplary simulation result of a coupling loss amount in an optical device according to each exemplary embodiment. A model 1400 illustrated in FIG. 14 is a model that is modeled on an optical receiving device that includes the light receiving element 140 and the TIA 150, among optical devices 100 according to above-described respective exemplary embodiments. An optical waveguide 1410 of the model 1400 corresponds to the core 111 of the optical waveguide 110. A lens 1420 of the model 1400 corresponds to the lens 160, or a combination of the lenses 160 and 810 of the optical device 100. A light receiving element 1430 of the model 1400 corresponds to the light receiving element 140 of the optical device 100.

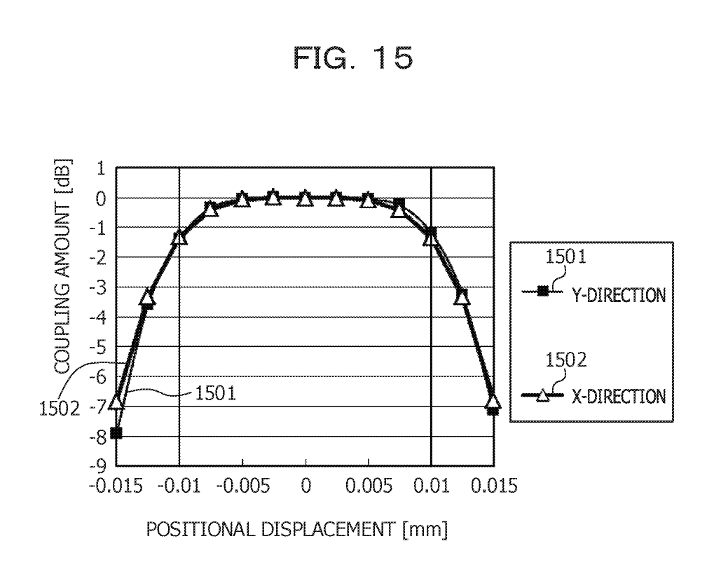

FIG. 15 illustrates a simulation result obtained through a ray tracing method on an optical coupling amount in the light receiving element 1430 in a case where the light receiving element 1430 is moved with respect to the lens 1420. In FIG. 15, the horizontal axis represents a positional displacement [mm] of the light receiving element 1430 with respect to the lens 1420, and the vertical axis represents an optical coupling amount [dB] in the light receiving element 1430. When the positional displacement is 0 [mm] in the horizontal axis, it indicates a state where the optical coupling amount is maximum (the coupling loss amount is minimum), that is, no positional displacement is present between the lens 1420 and the light receiving element 1430.

A simulation result 1501 indicates a simulation result of a relationship between a Y-direction positional displacement of the light receiving element 1430 with respect to the lens 1420, and an optical coupling amount. The Y-direction is a propagation direction of light in the optical waveguide 1410 (a horizontal direction in FIG. 14).

A simulation result 1502 indicates a simulation result of a relationship between an X-direction positional displacement of the light receiving element 1430 with respect to the lens 1420 and an optical coupling amount. The X-direction is an arrangement direction of a light receiving portion in the light receiving element 1430 (a depth direction in FIG. 14).

As illustrated in the simulation results 1501 and 1502, when the positional displacement of the light receiving element 1430 with respect to the lens 1420 is within a range of ±10 [μm], a decrease of the optical coupling amount in the light receiving element 1430 is suppressed to about 1 [dB].

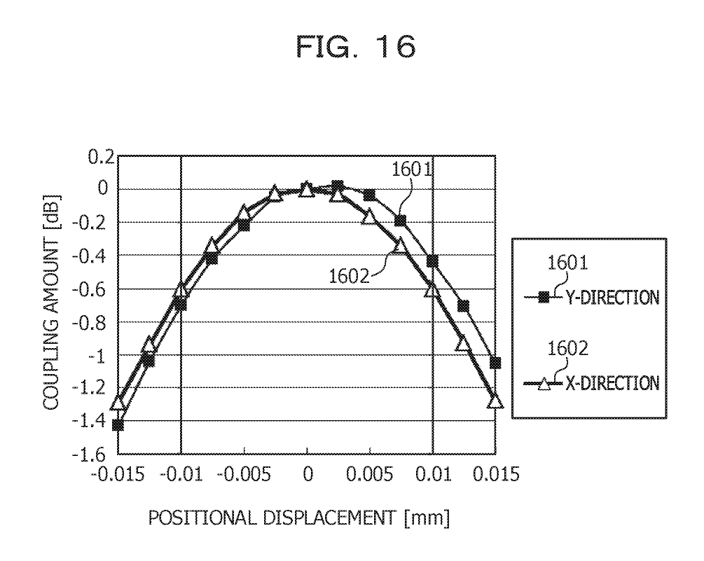

FIG. 16 illustrates a simulation result obtained through a ray tracing method on an optical coupling amount in the light receiving element 1430 in a case where the optical waveguide 1410 is moved with respect to the lens 1420. In FIG. 16, the horizontal axis represents a positional displacement [mm] of the optical waveguide 1410 with respect to the lens 1420, and the vertical axis represents an optical coupling amount [dB] in the light receiving element 1430. When the positional displacement is 0 [mm] in the horizontal axis, it indicates a state where the optical coupling amount is maximum (the coupling loss amount is minimum), that is, no positional displacement is present between the lens 1420 and the optical waveguide 1410.

A simulation result 1601 indicates a simulation result of a relationship between a Y-direction positional displacement of the optical waveguide 1410 with respect to the lens 1420 and an optical coupling amount. A simulation result 1602 indicates a simulation result of a relationship between an X-direction positional displacement of the optical waveguide 1410 with respect to the lens 1420 and an optical coupling amount.

As illustrated in the simulation results 1601 and 1602, when the positional displacement of the optical waveguide 1410 with respect to the lens 1420 is within a range of ±10 [μm], a decrease of the optical coupling amount in the light receiving element 1430 is suppressed to about 0.5 [dB].

As illustrated in FIGS. 14 to 16, it can be found that in the light receiving element 140 with an extremely small diameter, a coupling loss amount of light in the light receiving element 140 may be suppressed within a range of a positional displacement of an assumed mounting accuracy (e.g., ±10 [μm]).

For example, when an optical element such as, for example, a light receiving element or a light emitting element, a lens, and a printed circuit board are formed as separate parts, it is required to mount these parts so as to suppress a positional displacement between the lens and the printed circuit board as well as a positional displacement between the optical element and the lens. In contrast, according to the above-described respective exemplary embodiments, since the lens 160 is integrated on the printed circuit board 130 using an inkjet method, the lens 160 may be simply formed with high precision on the printed circuit board 130. Therefore, the manufacturing efficiency of the optical device 100 may be improved.

As described above, according to the manufacturing method, the printed circuit board, and the optical device, a lens having a small curvature radius may be positioned and formed with high precision.

For example, in a high-speed optical communication, an optical transceiver is required to convert a high-speed electrical signal to an optical signal.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A method of manufacturing a printed circuit board, the method comprising:
forming an electrode layer on one surface of a substrate;
forming a through hole that penetrates the substrate and the electrode layer, wherein an inner diameter of the through hole in the electrode layer is smaller than an inner diameter of the through hole in the substrate;
dropping a curable liquid that has a liquid-repellency with respect to the substrate, on a substrate portion in the through hole from an opposite side to the electrode layer; and
curing the liquid dropped on the substrate portion in the through hole to form a lens.

2. The method according to claim 1, wherein the lens is condensates light passing through the through hole.

3. The method according to claim 1, wherein the liquid is a liquid that is cured by irradiation of ultraviolet (UV) rays, and
the lens is formed by irradiating UV rays to the liquid dropped on the substrate portion in the through hole.

4. The method according to claim 1, further comprising:
forming a stepped portion which surrounds the through hole and has a step on a surface of the electrode layer at an opposite side to the substrate;
dropping a curable liquid on an electrode layer portion in the through hole from the opposite side to the substrate; and
curing the liquid dropped on the electrode layer portion in the through hole to form a second lens that is different from the lens.

5. The method according to claim 4, wherein an amount of the liquid dropped on the electrode layer portion in the through hole is adjusted such that the liquid is supported by any one edge among a plurality of edges formed by the stepped portion of the electrode layer.

6. The method according to claim 4, wherein, after the lens is formed on the substrate portion in the through hole, the curable liquid is dropped on the electrode layer portion in the through hole from the opposite side to the substrate such that the curable liquid is supported by the stepped portion, and
the liquid supported by the stepped portion is cured.

7. The method according to claim 1, further comprising:
forming a stepped portion which surrounds the through hole and has a step, and a convex portion surrounding the stepped portion, on a surface of the electrode layer at an opposite side to the substrate;
dropping a curable liquid on an electrode layer portion in the through hole from the opposite side to the substrate, and adjusting an amount of the liquid dropped on the electrode layer portion in the through hole such that the liquid dropped on the electrode layer portion in the through hole is supported by the stepped portion or the convex portion; and
curing the liquid supported by the stepped portion or the convex portion to form a second lens that is different from the lens.

8. The method according to claim 7, wherein an amount of the liquid dropped on the electrode layer portion in the through hole is adjusted such that the liquid is supported by any one edge among a plurality of edges formed by the stepped portion or the convex portion of the electrode layer.

9. A printed circuit board comprising:
a substrate;
an electrode layer formed on one surface of the substrate:
a through hole that penetrates the substrate and the electrode layer, wherein an inner diameter of the through hole in the electrode layer is smaller than an inner diameter of the through hole in the substrate; and
a lens formed on a substrate portion in the through hole.

10. An optical device comprising:
a printed circuit board including
a substrate,
an electrode layer formed on one surface of the substrate,
a through hole that penetrates the substrate and the electrode layer, wherein an inner diameter of the through hole in the electrode layer is smaller than an inner diameter of the through hole in the substrate, and
a lens formed on a substrate portion in the through hole;
an optical waveguide arranged on a surface of the printed circuit board at the electrode layer side, and emits light guided thereto to the through hole; and
a light receiving element arranged on a surface of the printed circuit board at an opposite side to the electrode layer, and receives light condensed by the lens when the light emitted from the optical waveguide passes through the through hole.

11. An optical device comprising:
a printed circuit board including
a substrate,
an electrode layer formed on one surface of the substrate,
a through hole that penetrates the substrate and the electrode layer, wherein an inner diameter of the through hole in the electrode layer is smaller than an inner diameter of the through hole in the substrate, and
a lens formed on a substrate portion in the through hole;
a light emitting element arranged on a surface of the printed circuit board at an opposite side to the electrode layer, and emits light to the through hole; and
an optical waveguide arranged on a surface of the printed circuit board at the electrode layer side, and receives and guides light condensed by the lens when the light emitted from the light emitting element passes through the through hole.
